(19) United States
(12) Patent Application Publication
(10) Pub. No.: US 2017/0062480 A1
(43) Pub. Date: Mar. 2, 2017

(54) FLEXIBLE SUBSTRATE AND METHOD FOR PREPARING THE SAME, DISPLAY SUBSTRATE, AND DISPLAY DEVICE

(71) Applicant: BOE TECHNOLOGY GROUP CO., LTD., Beijing (CN)

(72) Inventor: Zhao LI, Beijing (CN)

(73) Assignee: BOE TECHNOLOGY GROUP CO., LTD., Beijing (CN)

(21) Appl. No.: 14/914,210

(22) PCT Filed: Aug. 17, 2015
(86) PCT No.: PCT/CN2015/087225

§ 371 Date: Feb. 24, 2016

(30) Foreign Application Priority Data
Apr. 13, 2015 (CN) 201510172467.9

(51) Int. Cl. H01L 27/12

(52) U.S. Cl. CPC H01L 27/1218; H01L 27/1262

(57) ABSTRACT

The present disclosure belongs to the field of display technologies and provides a flexible substrate and a method for preparing the same, a display substrate and a display device, thereby solving the problems of poor heat absorption and heat-dissipating capability of the existing flexible substrates. The flexible substrate of the disclosure comprises a flexible base and a phase change material that is provided in the flexible base.

### CROSS REFERENCE TO RELATED APPLICATION

The present disclosure claims priority to the Chinese patent application No. 201510172467.9 filed in China on Apr. 13, 2015, the entire contents of which are incorporated by reference.

### TECHNICAL FIELD

The present disclosure relates to the field of display technologies, and in particular, to a flexible substrate and a method for preparing the same, and a display substrate and a display device that employ the flexible substrate.

### BACKGROUND

At present, polyimide (PI) is generally employed as the material of a flexible substrate. However, no matter during the forming of each element on the substrate or in the working state of a flexible display panel formed, each element formed will generate a large amount of heat, and the flexible substrate has poor capacities on the heat absorption and the heat release. Thus the heat accumulated on each element tends to be high, as a result, the life time of the elements will be shortened, or even the elements will be directly damaged.

### SUMMARY

As directed to the above problems of the existing flexible substrates, the present disclosure provides a flexible substrate with good heat absorption and heat dissipation performance and a method for preparing the same, and a display substrate and a display device that employ the flexible substrate.

The disclosure provides a flexible substrate, which includes a flexible base and a phase change material that is provided in the flexible base.

According to an embodiment of the disclosure, the phase change material is a microencapsuled phase change material and/or a nanoencapsulated phase change material.

According to an embodiment of the disclosure, the microencapsuled phase change material or the nanoencapsulated phase change material is at least one of the following encapsuled phase change materials: a) an encapsuled phase change material that takes n-decane and/or n-nonadecane and/or n-dodecane as the capsule core and urea-melamine-formaldehyde polymer as the capsule wall; b) an encapsuled phase change material that takes paraffin as the capsule core and polyurea or polyurethane as the capsule wall; c) an encapsuled phase change material that takes mixed paraffin as the capsule core and melamine resin as the capsule wall.

According to an embodiment of the disclosure, the flexible base is further provided with a fiber material, and the phase change material is contained in the fiber material.

According to an embodiment of the disclosure, the fiber material is a glass fiber.

According to an embodiment of the disclosure, the material of the flexible base is one selected from the group consisting of polyethylene terephthalate, polyethylene naphthalate, polycarbonate, polyether sulfone and polyimide.

Additionally, the present disclosure also provides a method for preparing a flexible substrate, wherein the flexible substrate includes a flexible base and a phase change material that is provided in the flexible base, and the method includes a step of forming a phase change material in the flexible base.

According to an embodiment of the disclosure, the step of forming a phase change material in the flexible base specifically includes:

preparing a raw material solution of the flexible base, and mixing a phase change material in the raw material solution of the flexible base;

forming a flexible base film with the phase change material by coating; and

curing the flexible base film with the phase change material.

According to an embodiment of the disclosure, the method further includes a step of implanting the phase change material into the fiber material before the step of forming the phase change material in the flexible base.

According to an embodiment of the disclosure, the phase change material is a microencapsuled phase change material and/or a nanoencapsulated phase change material.

The present disclosure provides a display substrate, which includes the above flexible substrate.

The disclosure provides a display device, which includes the above display substrate.

In the flexible substrate of the present disclosure, a phase change material is provided in the flexible base, thereby the substrate of the present disclosure may have good heat absorption and heat dissipation capabilities. Therefore, by applying the flexible substrate of the disclosure to a display substrate, the heat generated during the preparation process of a display substrate (especially, the heat generated by laser employed in the preparation process) may be well absorbed and released, so that it may be avoided that the performance of each element formed (i.e., thin-film transistor and organic electroluminescent apparatus, etc.) is influenced. Moreover, by applying the flexible substrate to a display device, during the working process of the display device, the large amount of heat generated by its internal circuit may be absorbed and released by the phase change material in the flexible substrate, so that the phenomenon may be avoided that the life time of the display device is influenced due to the aging of elements in the circuit.

### BRIEF DESCRIPTION OF THE DRAWINGS

FIG. 1 shows a schematic diagram of one example of the flexible substrate of the disclosure;

FIG. 2 shows a schematic diagram of another example of the flexible substrate of the disclosure; and

FIG. 3 shows a schematic diagram of still another example of the flexible substrate of the disclosure.

### REFERENCE OF THE DRAWING

10 a flexible substrate;
11 a flexible base;
12 a phase change material;
12-1 a microencapsuled phase change material and/or a nanoencapsulated phase change material;
121 a fiber

### DETAILED DESCRIPTION OF EMBODIMENTS

In order to make one skilled in the art better understand the technical solutions of the present disclosure, the present disclosure will be further described in detail in conjunction with the drawings and the following embodiments. However, the present disclosure is not limited to these embodiments.

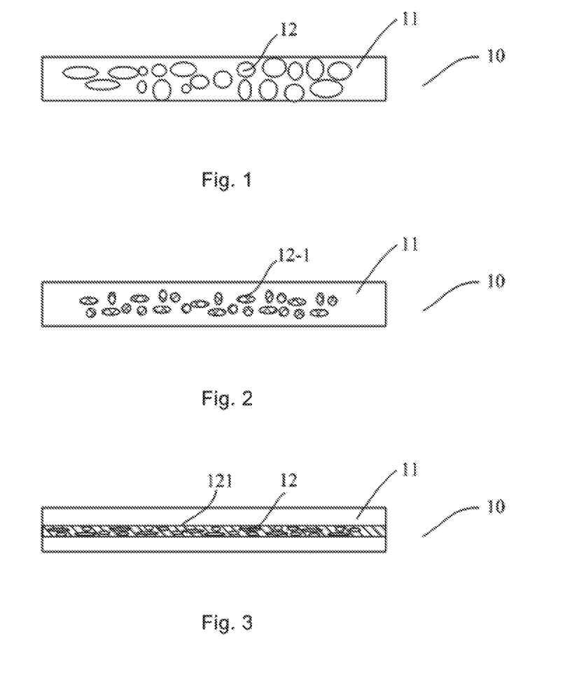

As shown in FIG. 1, this embodiment provides a flexible substrate 10, which includes a flexible base 11 and a phase change material 12 that is provided in the flexible base 11.

In the disclosure, the phase change material 12 refers to a substance that can change the physical properties thereof and provide latent heat as the temperature changes. The process for transforming physical property is referred to as a phase-change process; at this time, the phase change material 12 will absorb or release a large amount of latent heat by the phase-change process. For example, for solid-liquid phase change, when the phase change material 12 is heated to its melting temperature, a solid state-to-liquid state phase change will occur. During the melting process, the phase change material 12 absorbs and stores a large amount of latent heat; and when the phase change material 12 is cooled, a liquid state-to-solid state reverse phase transition occurs, and the heat stored in the phase change material 12 is dissipated into the environment in a certain temperature range. During the two phase-change processes, the energy stored or released is referred to as phase-change latent heat. When the physical state changes, the temperature of the phase change material 12 itself almost keeps constant before the phase change is completed, thus a wide temperature profile is formed; although the temperature is kept constants, the latent heat absorbed or released is quite great.

By providing a phase change material 12 in the flexible base 11 of the flexible substrate 10 of the disclosure, the flexible substrate 10 of the disclosure may have good heat absorption and heat dissipation capability. Thereby, by applying the flexible substrate 10 of the disclosure to a display substrate, the heat generated during the preparation process of a display substrate, especially the heat generated by laser employed in a preparation process, may be well absorbed and released, so that it may be avoided that the performance of each element formed (i.e., thin-film transistor and organic electroluminescent apparatus, etc.) is influenced. Moreover, by applying the flexible substrate 10 to a display device, during the working process of the display device, the large amount of heat generated its internal circuit may be absorbed and released by the phase change material 12 in the flexible substrate 10, so that the phenomenon may be avoided that the life time of the display device is influenced due to the aging of elements in the circuit.

According to another embodiment of the disclosure, as shown in FIG. 2, the phase change material 12 in this embodiment is at least one of a microencapsuled phase change material 12-1 and a nanoencapsulated phase change material 12-1. The microencapsuled phase change material (MCPCM) 12-1 is a micron-level composite phase change material obtained by encapsulating the phase change material 12. The phase-change substance in the MCPCM (i.e., the phase change material) is encapsulated in ball-shaped capsules, so that the problems of leakage, phase separation and corrosivity, etc. of the ordinary phase change material 12 may be effectively solved, which is favorable for improving the application performance of the ordinary the phase change material 12 and widening the application field of the phase-change heat storage technology. The size of the microencapsuled phase change material 12-1 is the largest grain size in its plane projection, and it may be determined via SEM observation. In the disclosure, the size of the microencapsuled phase change material 12-1 is in the range of from 0.1 μm to several hundred micrometers, and it may be from 1 μm to 200 μm, from 2 μm to 100 μm and from 5 μm to 80 μm, preferably from 10 μm to 50 μm, and more preferably from 20 μm to 30 μm. For the nanoencapsulated phase change material (NCPCM) 12-1, because the capsule size decreases from micro-level to nano-level, the surface area-volume ratio of the capsule increases, and it is more favorable for improving the heat-transfer rate of the phase change material 12, while the advantages of the microencapsuled phase change material 12-1 is maintained. At the same time, during application, the possibility of damage due to collision between grains in long-time use may be greatly lowered. The size of the nanoencapsulated phase change material 12-1 is the largest grain size, and it may be determined via TEM observation. In the present disclosure, the size of the nanoencapsulated phase change material 12-1 is in the range of from 10 nm to several hundred nanometers, and it may be in the range of from 10 nm to 200 nm, from 15 nm to 100 nm and from 20 nm to 80 nm, preferably from 10 nm to 50 nm, and more preferably from 20 nm to 30 nm. Moreover, both the microencapsuled phase change material 12-1 and the nanoencapsulated phase change material 12-1 consists of capsule cores and capsule walls that encapsulate the capsule cores, the phase-change heat is about from 100 to 200 J/g, and certain deformation may be endured, thus the flexibility of the flexible substrate 10 will not be influenced.

According to another embodiment of the disclosure, the phase change material 12 simultaneously contains the microencapsuled phase change material 12-1 and the nanoencapsulated phase change material 12-1. The ratio of the microencapsuled phase change material 12-1 to the nanoencapsulated phase change material 12-1 is not particularly limited, and the preferred weight ratio is 20-80:80-20. The ratio of the encapsulated phase change material (i.e., the microencapsuled phase change material 12-1 and/or the nanoencapsulated phase change material 12-1) in the phase change material 12 is not particularly limited, but preferably from 50% to 100% by weight, more preferably from 85% to 100% by weight, and most preferably 100% by weight.

According to one embodiment of the disclosure, the microencapsuled phase change material 12-1 and the nanoencapsulated phase change material 12-1 are preferably at least one of the following encapsulated phase change materials: a) an encapsulated phase change material that takes n-decane and/or n-nonadecane and/or n-dodecane as the capsule core and urea-melamine-formaldehyde polymer as the capsule wall; b) an encapsulated phase change material that takes paraffin as the capsule core and polyurea or polyurethane as the capsule wall; c) an encapsulated phase change material that takes mixed paraffin as the capsule core and melamine resin as the capsule wall. However, it may be understood that in this embodiment, the microencapsuled phase change material 12-1 and the nanoencapsulated phase change material 12-1 are not limited to the above three types, and other microencapsuled phase change materials 12-1 nanoencapsulated phase change materials 12-1 may also be employed.

The phase-change temperature of the above phase change materials is in a range of 20 to 40° C. In the present disclosure, the weight ratio of the phase change material relative to the flexible base 11 may be properly adjusted as required.

According to one embodiment of the disclosure, the flexible base 11 may also be provided with a fiber material 121, and the phase change material 12 is contained in the fiber material 121. In other words, in this embodiment, the phase change material 12 is implanted in the fiber material 121.

According to one embodiment of the disclosure, the fiber material may be glass fiber. By providing the fiber material 121 in the flexible base 11, the phase change material may be distributed more uniformly in the flexible base, thereby the form stability may be improved.

The method for implanting the phase change material 12 in the fiber material 121 may be a well-known method in this field.

According to one embodiment of the disclosure, a well-known material formerly taken as a flexible base may be employed as the material of the flexible base 11. Preferably, it may be one selected from the group consisting of polyethylene terephthalate (PET), polyethylene naphthalate (PEN), polycarbonate (PC), polyether sulfone (PES) and polyimide (PI).

According to one embodiment of the disclosure, there provides a method for preparing a flexible substrate, wherein the flexible substrate includes a flexible base and a phase change material that is provided in the flexible base, and the preparation method includes: a step of containing the phase change material in the flexible base.

According to one embodiment of the disclosure, the step of containing the phase change material in the flexible base specifically includes:

preparing a raw material solution of the flexible base, and mixing a phase change material in the raw material solution of the flexible base;

coating the mixed solution to form a flexible base film with the phase change material; and

curing the flexible base film with the phase change material, thus forming a flexible substrate.

The raw material solution of the flexible base (a suitable curing agent may be contained as required for curing), the phase change material and the relative ratio thereof may be selected according to the performance requirements of the flexible substrate. The mixed solution is coated by a well-known method in this field to form a flexible base film with the phase change material. The method for curing the flexible base film with the phase change material is not particularly limited, and methods such as heat curing, light curing and crosslink curing, etc., may be employed.

According to one embodiment of the disclosure, before containing the phase change material in the flexible base, the phase change material may be implanted into the fiber material 121, and then the fiber material 121 may be dispersed in the flexible base solution. With the curing of the flexible base film, the fiber material implanted with the phase change material 12 is dispersed in the flexible substrate, Because the fiber material 121 has good toughness, by providing the fiber material 121 implanted with the phase change material in the flexible substrate, not only the adaptability of the flexible substrate to temperature can be improved, but also the bending performance of the flexible substrate can be improved.

According to another embodiment of the disclosure, the above phase change material 12 is at least one of the above microencapsuled phase change material 12-1 and the above nanoencapsulated phase change material 12-1. Preferably, the microencapsuled phase change material 12-1 and the nanoencapsulated phase change material 12-1 are contained simultaneously. The ratio of the microencapsuled phase change material 12-1 to the nanoencapsulated phase change material 12-1 is not particularly limited, and the preferred weight ratio is 20-80:80-20. The ratio of the encapsulated phase change material (i.e., the microencapsuled phase change material 12-1 and/or the nanoencapsulated phase change material 12-1) in the phase change material 12 is not particularly limited, but preferably 50%-100% by weight, more preferably 85%-100% by weight, and most preferably 100% by weight.

According to one embodiment of the disclosure, the microencapsuled phase change material 12-1 and the nanoencapsulated phase change material 12-1 are preferably at least one of the following encapsulated phase change materials: a) an encapsulated phase change material that takes n-decane and/or n-nonadecane and/or n-dodecane as the capsule core and urea-melamine-formaldehyde polymer as the capsule wall; b) an encapsulated phase change material that takes paraffin as the capsule core and polyurea or polyurethane as the capsule wall; c) an encapsulated phase change material that takes mixed paraffin as the capsule core and melamine resin as the capsule wall. However, it may be understood that in this embodiment, the microencapsuled phase change material 12-1 and the nanoencapsulated phase change material 12-1 are not limited to the above three types, and other microencapsuled phase change materials 12-1 and nanoencapsulated phase change materials 12-1 may also be employed.

FIG. 3 shows another embodiment of the disclosure, wherein, after a fiber material 121 implanted with a phase change material 12 is provided in the above flexible base, a first flexible sub-base and a second flexible sub-base are respectively formed on the upper side and the lower side thereof, thereby constituting a stacked flexible base 11. The materials that constitute the first flexible sub-base and the second flexible sub-base are preferably one selected from the group consisting of polyethylene terephthalate (PET), polyethylene naphthalate (PEN), polycarbonate (PC), polyether sulfone (ES) and polyimide (PI), and they may be same or be different. However, the material of the flexible base is not limited to the above several materials, and materials for flexible bases well-known to one skilled in the art may also be employed, which will not be listed one by one. More preferably, the flexible base (including a first flexible sub-base and a second flexible sub-base) is consisted of one and the same polymer. Additionally, only one of the first flexible sub-base and the second flexible sub-base may be provided, or multi-layers of flexible sub-base may be provided.

The preparation method, thickness and stacking method of the flexible sub-base are not particularly limited, and they may be selected properly as required.

Correspondingly, this embodiment further provides a display substrate, which includes the above flexible substrate. Thus, for the display substrate of this embodiment, the heat generated during the preparation process of the display substrate, particularly the heat generated by laser employed in the process, may be well absorbed and released, so that it may be avoided that the performance of each element formed (i.e., thin-film transistor, organic electroluminescent apparatus, etc.) is influenced.

Correspondingly, this embodiment further provides a display device, which include the above display substrate. Thus, during the working process of the display device, the large amount of heat generated by its internal circuit may be absorbed and released by the phase change material in the flexible substrate, so that the phenomenon may be avoided that the life time of the display device is influenced due to the aging of elements in the circuit.

The display device may be any product or component that has a display function, for example, mobile phone, tablet computer, TV set, display, notebook computer, digital photo frame and navigator, etc.

However, the display device of this embodiment may also include other conventional structures, for example, a display driving unit, etc.

It may be understood that, the above embodiments are only exemplary embodiments employed for illustrating the principles of the disclosure; however, the disclosure is not limited thereto. For one of ordinary skills in the art, various variations and improvements may be made without departing from the spirit and essence of the disclosure. All these variations and improvements should be regarded as falling into the protection scope of the disclosure.

1. A flexible substrate, comprising a flexible base, wherein the flexible substrate further comprises a phase change material that is provided in the flexible base.

2. The flexible substrate according to claim 1, wherein, the phase change material is a microencapsuled phase change material and/or a nanoencapsulated phase change material.

3. The flexible substrate according to claim 2, wherein, the microencapsuled phase change material and the nanoencapsulated phase change material are at least one of the following encapsulated phase change materials: a) an encapsulated phase change material that takes n-decane and/or n-nonadecane and/or n-dodecane as a capsule core and urea-melamine-formaldehyde polymer as a capsule wall; b) an encapsulated phase change material that takes paraffin as a capsule core and polyurea or polyurethane as a capsule wall; c) an encapsulated phase change material that takes mixed paraffin as a capsule core and melamine resin as a capsule wall.

4. The flexible substrate according to claim 1, wherein, the flexible base is further provided with a fiber material, and the phase change material is contained in the fiber material.

5. The flexible substrate according to claim 4, wherein, the fiber material is glass fiber.

6. The flexible substrate according to claim 1, wherein, a material of the flexible base is any one of polyethylene terephthalate, polyethylene naphthalate, polycarbonate, polyether sulfone and polyimide.

7. The flexible substrate according to claim 1, wherein, the flexible substrate further comprises a flexible sub-base.

8. A method for preparing a flexible substrate, comprising: a step of forming a phase change material in a flexible base.

9. The method for preparing a flexible substrate according to claim 8, wherein, the step of forming a phase change material in a flexible base comprises:
preparing a raw material solution of the flexible base, and mixing a phase change material into the raw material solution of the flexible base;
forming a flexible base film with the phase change material by coating; and
curing the flexible base film with the phase change material.

10. The method for preparing a flexible substrate according to claim 8, wherein, the method further comprises: a step of implanting the phase change material into a fiber material before the step of forming a phase change material in a flexible base.

11. The method for preparing a flexible substrate according to claim 8, wherein, the phase change material is a microencapsuled phase change material and/or a nanoencapsulated phase change material.

12. The flexible substrate according to claim 11, wherein, the microencapsuled phase change material and the nanoencapsulated phase change material are at least one of the following encapsuled phase change materials: a) an encapsuled phase change material that takes n-decane and/or n-nonadecane and/or n-dodecane as a capsule core and urea-melamine-formaldehyde polymer as a capsule wall; b) an encapsuled phase change material that takes paraffin as a capsule core and polyurea or polyurethane as a capsule wall; c) an encapsuled phase change material that takes mixed paraffin as a capsule core and melamine resin as a capsule wall.

13. A display substrate, comprising the flexible substrate according to claim 1.

14. A display device, comprising the display substrate according to claim 13.

15. The flexible substrate according to claim 2, wherein, the flexible base is further provided with a fiber material, and the phase change material is contained in the fiber material.

16. The flexible substrate according to claim 3, wherein, the flexible base is further provided with a fiber material, and the phase change material is contained in the fiber material.

17. The flexible substrate according to claim 2, wherein, a material of the flexible base is any one of polyethylene terephthalate, polyethylene naphthalate, polycarbonate, polyether sulfone and polyimide.

18. The flexible substrate according to claim 3, wherein, a material of the flexible base is any one of polyethylene terephthalate, polyethylene naphthalate, polycarbonate, polyether sulfone and polyimide.

19. The method for preparing a flexible substrate according to claim 9, wherein, the phase change material is a microencapsuled phase change material and/or a nanoencapsulated phase change material.

20. The method for preparing a flexible substrate according to claim 10, wherein, the phase change material is a microencapsuled phase change material and/or a nanoencapsulated phase change material.
